(19) United States
(12) Patent Application Publication
(10) Pub. No.: US 2026/0235650 A1
(43) Pub. Date: Aug. 13, 2026

(54) POWER DETECTION CIRCUIT AND METHOD OF OPERATING THE SAME

(71) Applicant: CHICONY POWER TECHNOLOGY CO., LTD., New Taipei City (TW)

(72) Inventors: Ssu-Hao WANG, New Taipei City (TW); Tso-Jen PENG, New Taipei City (TW); Liang-Ting KUO, New Taipei City (TW); Mao-Song PAN, New Taipei City (TW)

(21) Appl. No.: 19/216,996

(22) Filed: May 23, 2025

(30) Foreign Application Priority Data
Feb. 10, 2025 (TW) 114104886

(51) Int. Cl. G01R 21/14; G01K 7/16; G01R 21/06

(52) U.S. Cl. CPC G01R 21/14; G01K 7/16; G01R 21/06

(57) ABSTRACT

A power detection circuit is configured in a power supply unit having a primary side and a secondary side. The power detection circuit includes a secondary-side controller, a first voltage detection circuit, a second voltage detection circuit, and a current detection circuit. The secondary-side controller calculates an output power according to an output voltage and an output current of the power supply unit, acquires a first efficiency value according to the output power and an efficiency conversion table inside the secondary-side controller, and calculates an input power of the power supply according to the first efficiency value and the output power.

### BACKGROUND

### Technical Field

The present disclosure relates to a power detection circuit and a method of operating the same, and particularly to a power detection circuit capable of estimating an input power and a method of operating the same.

### Description of Related Art

The statements in this section merely provide background information related to the present disclosure and do not necessarily constitute prior art.

Issues such as carbon tax and carbon footprint are becoming clearer, and how to calculate the carbon emissions of products will be an issue in the future. Specifically, carbon tax and carbon footprint are mainly based on the premise of assigning a price to carbon dioxide (i.e., carbon pricing), and treating carbon dioxide as a commodity that can be traded, transferred, and taxed. The reason why a price is set for “carbon dioxide” is that it accounts for the highest proportion of all greenhouse gas emissions and has become a key priority for control by various countries and international organizations. As the global energy conservation and environmental protection movement is underway, various countries have introduced relevant carbon taxes and energy conservation standards. In order to meet environmental protection requirements, high power density and high efficiency are inevitable trends.

In general, most use the carbon emissions generated by product manufacturing as the standard. However, when it comes to power supply products such as power supplies (PSUs), the carbon emissions from their operation cannot be underestimated due to their long hours of operation. Therefore, it is still necessary to understand the carbon emissions generated by the operation of such products in order to meet environmental protection requirements. Furthermore, the carbon emissions of a power supply during operation are generally calculated by converting the input power of the power supply into the kWh consumed. However, in a power supply having a primary side and a secondary side, conventional input power detection requires reading the voltage and current of the primary side and then transmitting them to the secondary side through an optical coupler for calculation. Therefore, if a conventional power supply is to meet the requirement of power calculation, it must be configured with an additional detection circuit and an optical coupler on the primary side, which increases the cost of the power supply and requires additional configuration space.

Therefore, how to design a power detection circuit and a method of operating the same to estimate the input power of a power supply by acquiring secondary-side parameters of the power supply has become a critical topic in this field.

### SUMMARY

In order to solve the above-mentioned problems, the present disclosure provides a power detection circuit. The power detection circuit is configured in a power supply having a primary side and a secondary side. The power detection circuit includes a secondary-side controller, a first voltage detection circuit, a second voltage detection circuit, and a current detection circuit. The secondary-side controller is configured in the secondary side. The first voltage detection circuit is coupled to the secondary-side controller, and provides a detection voltage according to a winding voltage of the secondary side. The second voltage detection circuit is coupled to the secondary-side controller and an output terminal of the power supply, and detects an output voltage of the output terminal. The current detection circuit is coupled to the secondary-side controller and the output terminal, and detects an output current of the output terminal. The secondary-side controller calculates an input voltage of the power supply according to the detection voltage, and acquires an efficiency conversion table under different output current conditions according to the input voltage. The secondary-side controller calculates an output power according to the output voltage and the output current, acquires a first efficiency value of the power supply under the output current conditions by comparing the output power with the efficiency conversion table, and calculates an input power of the power supply according to the first efficiency value and the output power.

In order to solve the above-mentioned problems, the present disclosure provides a method of operating a power detection circuit. The power detection circuit is configured in a power supply comprising a primary side and a secondary side. The method includes steps of: detecting an output voltage and an output current of an output terminal of the power supply; providing a detection voltage according to a winding voltage of the secondary side; calculating an input voltage of the power supply according to the detection voltage, and acquiring an efficiency conversion table under different output current conditions according to the input voltage; calculating an output power according to the output voltage and the output current, and acquiring a first efficiency value of the power supply under the output current conditions by comparing the output power with the efficiency conversion table; calculating an input power of the power supply according to the first efficiency value and the output power.

The main purpose and effect of the present disclosure is that the power supply can use the power detection circuit to detect the parameters acquired on the secondary side, and acquire the input power of the power supply through the estimation of the secondary side controller. Therefore, the power supply can use fewer components to detect the parameters of the secondary side to realize the function of estimating the input power, thereby reducing the circuit cost and the complexity of the circuit design.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a block circuit diagram of a power supply according to the present disclosure.

FIG. 2 is a temperature efficiency curve diagram of the power supply according to the present disclosure.

FIG. 3 is a circuit block diagram of the power supply equipped with a test circuit according to the present disclosure.

FIG. 4 is a circuit diagram of a current detection circuit and a temperature detection circuit according to the present disclosure.

FIG. 5A is a block circuit diagram of a first voltage detection circuit according to a first embodiment of the present disclosure.

FIG. 5B is a block circuit diagram of the first voltage detection circuit according to a second embodiment of the present disclosure.

FIG. 5C is a block circuit diagram of the first voltage detection circuit according to a third embodiment of the present disclosure.

FIG. 6 is a flowchart of a method of operating the power detection circuit according to the present disclosure.

FIG. 7A is a flowchart of a method of calculating electric power of a power supply according to the present disclosure.

FIG. 7B is a waveform diagram of the method of calculating electric power of the power supply according to the present disclosure.

### DETAILED DESCRIPTION

Reference will now be made to the drawing figures to describe the present disclosure in detail. It will be understood that the drawing figures and exemplified embodiments of present disclosure are not limited to the details thereof.

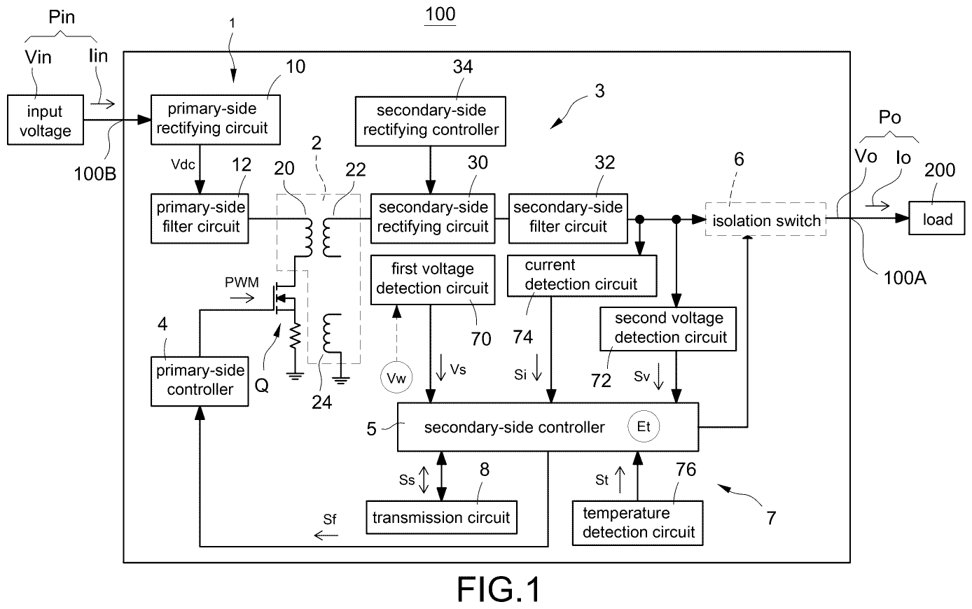

Please refer to FIG. 1, which shows a block circuit diagram of a power supply according to the present disclosure. The power supply 100 receives an input voltage Vin, and converts the input voltage Vin into an output voltage Vo so as to provide the output voltage Vo from an output terminal 100A to supply power to a load 200. In particular, the structure of the main conversion circuit of the power supply 100 may be a switching converter with an isolation transformer, and it may be a power conversion circuit, for example but not limited to, a flyback converter, a forward converter, etc. Taking the flyback conversion circuit as an example, the power supply 100 includes a primary-side circuit 1, a transformer 2, a secondary-side circuit 3, a primary-side controller 4, and a secondary-side controller 5. A primary-side winding 20 and a secondary-side winding 22 of the transformer 2 divide the power supply 100 into a primary side and a secondary side.

Specifically, the primary-side circuit 1 and the primary-side controller 4 are disposed on the primary side of the power supply 100, and the secondary-side circuit 3 and the secondary-side controller 5 are disposed on the secondary side of the power supply 100. The primary-side circuit 1 may include, for example but not limited to, a primary-side rectifying circuit 10, a primary-side filter circuit 12, and a primary-side switch Q. The primary-side rectifying circuit 10 is coupled to the primary-side filter circuit 12, and the primary-side filter circuit 12 and the primary-side switch Q are coupled to the primary-side winding 20. The secondary-side circuit 3 may include, for example but not limited to, a secondary-side rectifying circuit 30 and a secondary-side filter circuit 32. The secondary-side rectifying circuit 30 is coupled to the secondary-side winding 22, and the secondary-side filter circuit 32 is coupled to the secondary-side rectifying circuit 30 and the output terminal 100A.

Furthermore, the secondary-side controller 5 provides a feedback signal Sf to inform the primary-side controller 4 according to the output voltage Vo provided by the power supply 100 and the output current Io required by the load 200 so that the primary-side controller 4 adjusts a pulse-width modulation signal PWM according to the feedback signal Sf. The primary-side rectifying circuit 10 converts the input voltage Vin into a DC voltage Vdc, and the primary-side controller 4 provides the pulse-width modulation signal PWM to control the switching (on/off) of the primary-side switch Q. Therefore, the primary-side filter circuit 12 stores/releases energy according to the DC voltage Vdc so that the transformer 2 couples energy from the primary-side winding 20 to the secondary-side winding 22 according to the energy storage/release of the primary-side filter circuit 12. Furthermore, after rectification by the secondary-side rectifying circuit 30 and filtering by the secondary-side filter circuit 32, the output voltage Vo is provided to the output terminal 100A. On the other hand, the transformer 2 may further include an auxiliary winding 24, and the auxiliary winding 24 mainly supplies power to peripheral devices (such as, but not limited to, the secondary-side controller 5, a fan, etc.) of the power supply 100 by coupling the primary-side winding 20.

In particular, the secondary-side rectifying circuit 30 may be controlled to switch synchronously with the primary-side switch Q by the secondary-side rectifying controller 34 shown in FIG. 1. However, it may also be rectified passively by passive components, such as but not limited to, diodes. Furthermore, the secondary-side controller 5 may or may not have a power transmission protocol (USB-PD, USB Power Delivery). When the secondary-side controller 5 has the power transmission protocol, the secondary side of the power supply 100 may further include an isolation switch 6 (indicated by a dotted line). After the secondary-side controller 5 and the load 200 complete a handshake communication, the secondary-side controller 5 turns on the isolation switch 6 to provide the output voltage Vo that meets the requirements of the load 200 to the output terminal 100A through the isolation switch 6 so as to avoid the risk that the power supply 100 erroneously provides the output voltage Vo that does not meet the requirements of the load 200 to the load 200, thereby causing the load 200 to fail or even be damaged.

Please refer to FIG. 1 again, the power supply 100 further includes a power detection circuit 7. The power detection circuit 7 includes the secondary-side controller 5, a first voltage detection circuit 70, a second voltage detection circuit 72, and a current detection circuit 74. The first voltage detection circuit 70 is coupled to the secondary-side controller 5, and provides a detection voltage Vs according to a secondary-side winding voltage Vw. The second voltage detection circuit 72 is coupled to the secondary-side controller 5 and the output terminal 100A, and detects the output voltage Vo of the output terminal 100A and provides a voltage signal Sv to the secondary-side controller 5. The current detection circuit 74 is coupled to the secondary-side controller 5 and the output terminal 100A, and detects the output current Io drawn by the load 200 and provides a current signal Si to the secondary-side controller 5.

In one embodiment, the main function of the secondary-side controller 5 is generally to provide the feedback signal Sf to the primary-side controller 4 according to the output voltage Vo provided by the power supply 100 and the output current Io required by the load 200. The secondary-side controller 5 may usually be a microprocessor MCU or a digital signal processor DSP. In general, this type of processor may usually write customized code to implement customized functions. In addition to the original function of controlling the power supply 100, the secondary-side controller 5 further includes the function of estimating an input power Pin using only the parameters (such as, but not limited to, the detection voltage Vs, the output voltage Vo, the output current Io, etc.) detected by the secondary side.

Specifically, since the magnitude of the winding voltage Vw can respond to the magnitude of the input voltage Vin, the secondary-side controller 5 can calculate the input voltage Vin of the power supply 100 according to the detection voltage Vs. There are many ways in which the first voltage detection circuit 70 can provide the detection voltage Vs through the winding voltage Vw so that the secondary-side controller 5 can estimate the input voltage Vin, which is represented by a dotted line and will be further described later. Furthermore, the secondary-side controller 5 acquires an efficiency conversion table Et under different output current conditions according to the input voltage Vin. In particular, the efficiency conversion table Et may be pre-written into the secondary-side controller 5, or the efficiency conversion table Et may be established by testing a test circuit, which will be further described below.

Afterward, the secondary-side controller 5 acquires the magnitudes of the output voltage Vo and the output current Io according to the voltage signal Sv and the current signal Si, and calculates an output power Po according to the output voltage Vo and the output current Io. Furthermore, the secondary-side controller 5 can compare the output power Po with the efficiency conversion table Et to acquire a first efficiency value of the power supply 100 under the current output current Io. Finally, the secondary-side controller 5 calculates the input power Pin of the power supply 100 according to the first efficiency value and the output power Po. For example, it is assumed that the output power Po is 36 W, the first efficiency value compared by the efficiency conversion table Et is 0.9, and therefore the secondary-side controller 5 can estimate the input power Pin at this time to be 40 W, and so on. Therefore, through the above-mentioned estimation method, fewer components (i.e., the original secondary-side controller 5 with the detection circuit) may be used to detect the parameters of the secondary side to realize the function of estimating the input power Pin, thereby achieving the effect of reducing circuit cost and circuit design complexity.

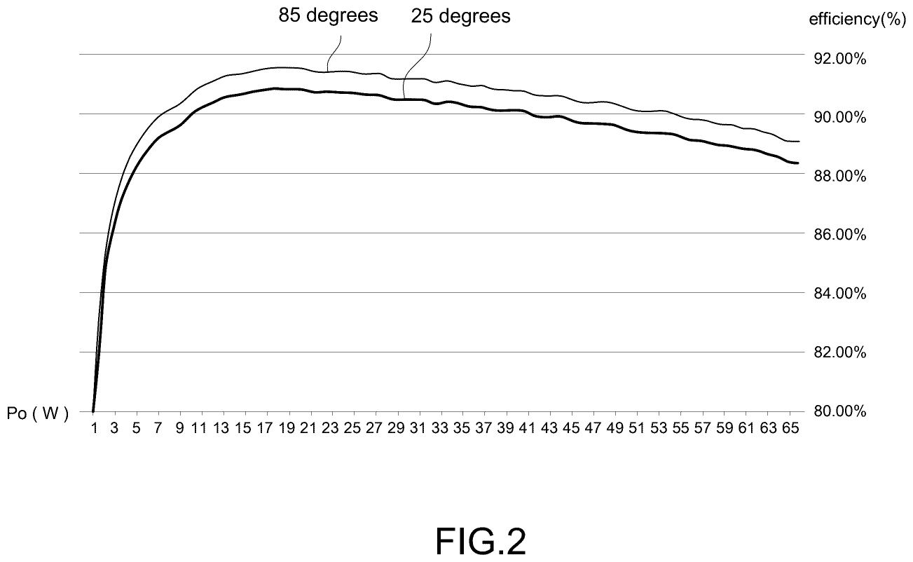

Please refer to FIG. 1 again, the power detection circuit 7 may optionally include a temperature detection circuit 76. The temperature detection circuit 76 is coupled to the secondary-side controller 5, and detects a first ambient temperature inside a casing (not shown) of the power supply 100 and provides a temperature signal St to the secondary-side controller 5. Please refer to FIG. 2, which shows a temperature efficiency curve diagram of the power supply according to the present disclosure, and it can be seen that the ambient temperature of the power supply 100 is related to the efficiency of the power supply 100. Specifically, under the same output power Po, when the temperature is higher, the efficiency of the power supply 100 is higher, and vice versa. Taking FIG. 2 as an example, when the ambient temperature of the power supply 100 is 25 degrees and the output power Po is 40 W, the efficiency is approximately 90%. However, at 85 degrees, the output power is roughly 92%. Therefore, in order to estimate the input power Pin more accurately, when acquiring the first efficiency value, the value of the first efficiency value may be shifted according to the first ambient temperature so as to acquire a more accurate input power Pin by adjusting the first efficiency value.

In particular, the power supply 100 can acquire the displacement of the first efficiency value under the influence of the ambient temperature through various manners. For example but not limited to, the power supply 100 may measure the efficiency curve at each ambient temperature by using a pre-testing manner. Alternatively, the power supply 100 may also acquire the displacement of the first efficiency value by using an interpolation manner. Specifically, the secondary-side controller 5 may preset a plurality of second ambient temperatures (taking the ambient temperatures of 25 degrees and 85 degrees in FIG. 2 as an example). Furthermore, the secondary-side controller 5 can acquire two efficiency curves under different output current conditions (corresponding to output power Po) according to the two second ambient temperatures so as to acquire two second conversion efficiency values under a specific output power Po, i.e., when the output power Po is 40 W, the second conversion efficiency values are 90% and 92% respectively. Therefore, when the secondary-side controller 5 acquires the current output power Po and the current first ambient temperature, the secondary-side controller 5 calculates a parameter difference between the first ambient temperature and two adjacent second ambient temperatures (i.e., the ambient temperatures are 25 degrees and 85 degrees) through the interpolation calculation to acquire a first efficiency value corresponding to the first ambient temperature.

For example, when the output power Po is 65W and the second ambient temperature is 25 degrees, the second efficiency value is 88%, and when the second ambient temperature is 85 degrees, the second efficiency value is 90%. Therefore, the efficiency value of a single output power (i.e., 1 W) may be regarded as 0.0333%/per degree, that is, (90%−88%)/(85 degrees−25 degrees)=2%/60 degrees=0.0333%/per degree. Therefore, when the output power Po is 65 W, the efficiency of the power supply 100 increases or decreases by 0.0333% when the ambient temperature increases or decreases by 1 degree. Therefore, if the power supply 100 measures that the current output power Po is 67 W, the corresponding first efficiency value may be estimated to be 89.398%, that is, (67−25)*0.0333%+88%=89.398%. Therefore, the power supply 100 can estimate the first efficiency value of the specific output power Po by means of interpolation calculation without acquiring a large number of parameters and their corresponding efficiency curves through pre-testing, thereby reducing a large amount of time cost of pre-testing. In addition, since the calculated displacement of the first efficiency value will be more accurate when the parameter difference is closer (for example but not limited to, the curve of 67 W is only 2 W different from the actual tested 65 W), the secondary-side controller 5 can add several more second ambient temperatures and their corresponding efficiency curves to increase the accuracy of the first efficiency value estimated by the power supply 100.

On the other hand, the power supply 100 may further include a transmission circuit 8, and the transmission circuit 8 is coupled to the secondary-side controller 5. The secondary-side controller 5 can communicate with an external device (not shown) through a transmission circuit 8 (via a transmission signal Ss) so that the transmission circuit 8 can transmit the parameters stored in the secondary-side controller 5 (for example, but not limited to, the parameters mentioned above, or the power parameters calculated according to the input power Pin and the running time of the power supply 100) to the external device (for example, but not limited to, physical or virtual devices uploaded to the system, cloud, host computer, etc.) in a wired or wireless manner. Alternatively, the external device may transmit parameters or control commands (such as, but not limited to, the efficiency conversion table Et, commands requesting parameter transmission, etc.) to control the secondary-side controller 5. Therefore, the power supply 100 can have edge computing and remote sensing functions.

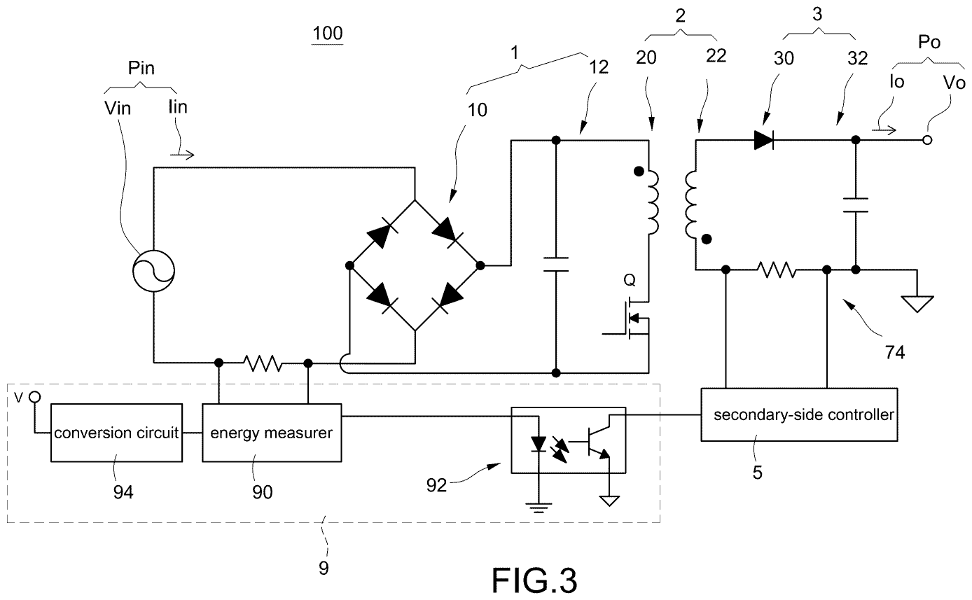

Please refer to FIG. 3, which shows a circuit block diagram of the power supply equipped with a test circuit according to the present disclosure, and also refer to FIG. 1 to FIG. 2. The difference between FIG. 3 and FIG. 1 is that FIG. 3 includes a testing circuit 9 externally applied to the power supply 100, and the testing circuit 9 includes an energy measurer 90 (E-Meter) and an optical coupler 92. Specifically, the power supply 100 can not only pre-write the efficiency conversion table Et into the secondary-side controller 5, but also establish the efficiency conversion table Et by measuring and transmitting the results to the secondary-side controller 5 by the external testing circuit 9 when the power supply 100 is operating. Furthermore, the energy measurer 90 is coupled to the input terminal 100B of the power supply 100, and the optical coupler 92 is coupled to the energy measurer 90 and the secondary-side controller 5. In one embodiment, the model of the energy measurer 90 may be, for example but not limited to, 78M6610, but is not limited thereto.

The energy measurer 90 mainly reads the input voltage Vin, the input current Iin and the power factor by coupling the input terminal 100B, and transmits the information to the secondary-side controller 5 through the optical coupler 92 so that the secondary-side controller 5 can establish the efficiency conversion table Et. Furthermore, after the efficiency conversion table Et is established, the energy measurer 90 may be removed so that the secondary-side controller 5 can solely estimate the input power Pin of the power supply 100 according to the secondary-side parameters. Furthermore, since the energy measurer 90 is an external device and may be removed when the power supply 100 is actually operating, the equipment cost of the power supply 100 can be greatly saved and the size of the power supply 100 can be greatly reduced. Therefore, the power supply 100 is particularly suitable for use in devices such as adapters that require a light, thin, and compact design.

On the other hand, the testing circuit 9 may further optionally include a conversion circuit 94, and the conversion circuit 94 is coupled to the energy measurer 90. The conversion circuit 94 is mainly used to convert an external voltage V into the working voltage Vcc to supply power to the energy measurer 90. Furthermore, the external voltage V may be provided by an external device, or may be taken from a voltage of any node of the power supply 100 (such as but not limited to, a DC voltage Vdc).

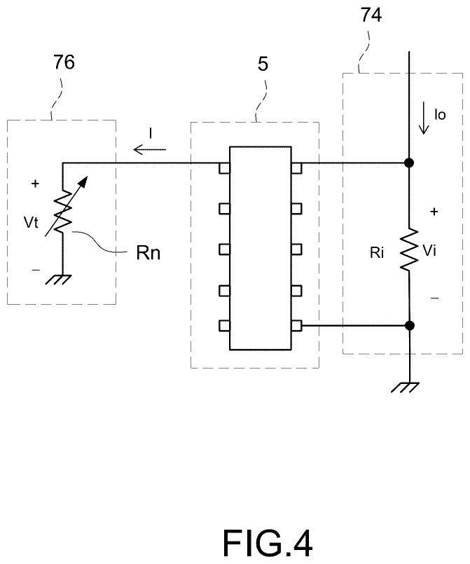

Please refer to FIG. 4, which shows a circuit diagram of a current detection circuit and a temperature detection circuit according to the present disclosure, and also refer to FIG. 1 to FIG. 3. The temperature detection circuit 76 may include a temperature-controlled resistor Rn, and the temperature-controlled resistor Rn is coupled to the secondary-side controller 5. The temperature-controlled resistor Rn generates a temperature-controlled resistance value according to the first ambient temperature, and the secondary-side controller 5 provides a current I through a current source (not shown) so that the temperature-controlled resistor Rn generates a temperature-controlled voltage Vt (i.e., the temperature signal St) according to the current I and the temperature-controlled resistance value. Furthermore, the secondary-side controller 5 can acquire the first ambient temperature according to the temperature-controlled voltage Vt so as to adjust the first efficiency value according to the first ambient temperature. In one embodiment, the temperature-controlled resistor Rn may be a negative temperature coefficient resistor (NTC), but is not limited thereto. Any resistor or other component that can change resistance value according to ambient temperature should be included in the scope of this embodiment. Furthermore, in one embodiment, in addition to the implementation of the temperature detection circuit 76 shown in FIG. 4, the power supply 100 has a variety of circuit structures that can implement the temperature detection circuit 76. Therefore, any implementation of the temperature detection circuit 76 that can determine the first ambient temperature according to the temperature-controlled voltage Vt should be included in the scope of this embodiment.

The current detection circuit 74 includes a current detection resistor Ri, and the current detection resistor Ri is coupled to the output terminal 100A and the secondary-side controller 5. When the output current Io flows through the current detection resistor Ri, a current detection voltage Vi (i.e., a current signal Si) is generated at the current detection resistor Ri. Therefore, the secondary-side controller 5 can acquire the magnitude of the output current Io according to the current detection voltage Vi. In one embodiment, in addition to the implementation of the current detection circuit 74 shown in FIG. 4, the power supply 100 has a variety of circuit structures that can implement the current detection circuit 74. Therefore, any implementation of the current detection circuit 74 that can determine the output current Io according to the current detection voltage Vi should be included in the scope of this embodiment. In addition, in one embodiment, the current detection circuit 74 is not limited to being coupled to the output terminal 100A to directly detect the output current Io, but may also be coupled to other positions of the power supply 100 (such as, but not limited to, the secondary-side winding 22, or other positions) to indirectly detect the output current Io.

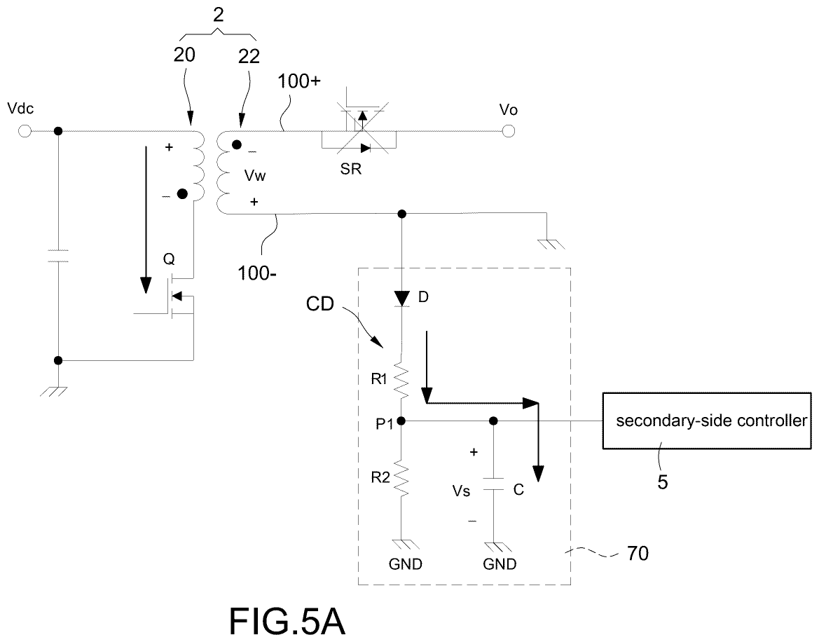

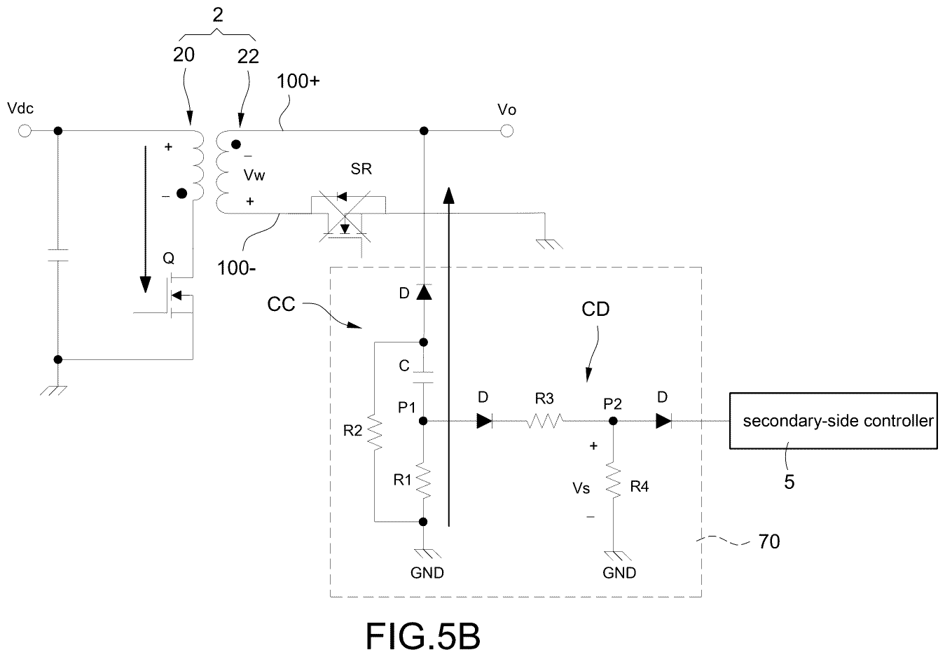

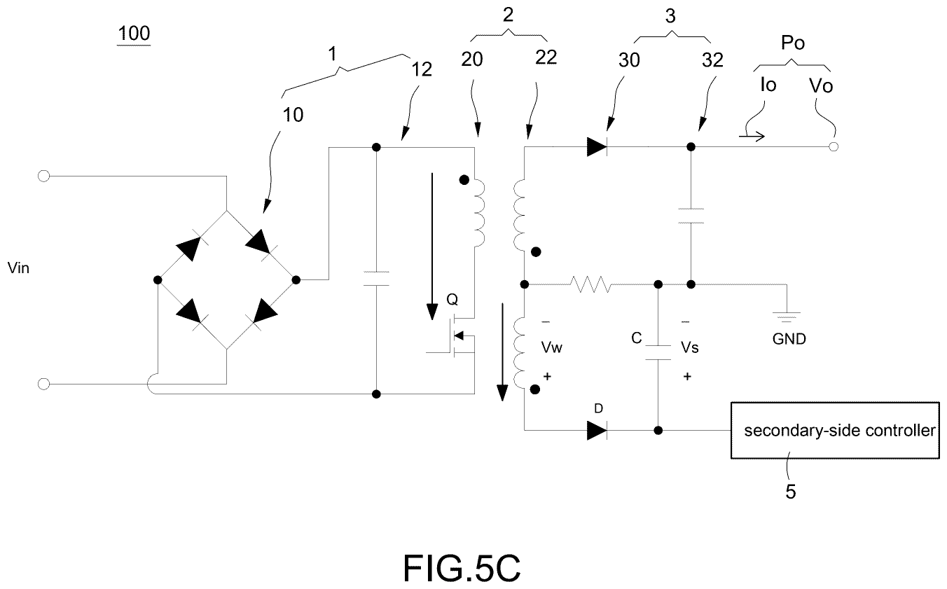

Please refer to FIG. 5A, which shows a block circuit diagram of a first voltage detection circuit according to a first embodiment of the present disclosure, and also refer to FIG. 1 to FIG. 4. In FIG. 5A, the secondary-side rectifying circuit 30 includes a secondary-side switch SR, and the secondary-side switch SR is configured at a bus positive terminal 100+ of the secondary side. The first voltage detection circuit 70 is coupled between a bus negative terminal 100− of the secondary side and a ground terminal GND, and the first voltage detection circuit 70 includes a voltage-dividing circuit CD. The voltage-dividing circuit CD is coupled between the bus negative terminal 100− of the secondary side and the ground terminal GND, and the voltage-dividing circuit CD includes a first resistor R1 and a second resistor R2 connected in series. Taking the flyback conversion circuit as an example, when the primary-side switch Q is turned on, the secondary-side switch SR is not turned on. In this condition, the primary-side current (indicated by arrows) flows from the primary-side winding 20 to the primary-side switch Q, and energy is coupled to the secondary-side winding 22 through the primary-side winding 20 to generate a winding voltage Vw at the secondary-side winding 22. Since the polarity of the primary-side winding 20 and the polarity of the secondary-side winding 22 are opposite (i.e., different dotted terminals) and the secondary-side switch SR is not turned on, the voltage-dividing circuit CD divides the winding voltage Vw (the current is represented by arrows) to generate the detection voltage Vs at a node P1 between the first resistor R1 and the second resistor R2. Furthermore, since when the primary-side switch Q is turned on and the secondary-side switch SR is not turned on, the magnitude of the winding voltage Vw responds to the magnitude of the DC voltage Vdc (which is, for example but not limited to, −Vdc*turns ratio), and the magnitude of the DC voltage Vdc corresponds to the magnitude of the input voltage Vin. Therefore, the detection voltage Vs can reflect the magnitude of the input voltage Vin so that the secondary-side controller 5 can convert the magnitude of the input voltage Vin according to the magnitude of the detection voltage Vs.

On the other hand, the first voltage detection circuit 70 may further optionally include a diode D and a capacitor C. The diode D is connected between the secondary-side winding 22 and the node P1 in series, and the capacitor C is connected to the second resistor R2 in parallel. The diode D is mainly used to prevent the current from being reversely flowed back to the secondary side from the first voltage detection circuit 70 when the secondary-side switch SR is switched. The capacitor C is mainly used to stabilize the voltage level of the detection voltage Vs when the secondary-side switch SR is switched so that the secondary-side controller 5 can more accurately determine the magnitude of the input voltage Vin.

Please refer to FIG. 5B, which shows a block circuit diagram of the first voltage detection circuit according to a second embodiment of the present disclosure, and also refer to FIG. 1 to FIG. 5A. The difference between the first voltage detection circuit 70 of FIG. 5B and that of FIG. 5A is that the secondary-side switch SR is disposed at the bus negative terminal 100−, and the first voltage detection circuit 70 is coupled between the bus positive terminal 100+ and the ground terminal GND. The first voltage detection circuit 70 includes a clamping circuit CC, and the clamping circuit CC is coupled between the bus positive terminal 100+ and the ground terminal GND. The clamping circuit CC includes a capacitor C and a first resistor R1 connected in series, and a second resistor R2 is connected to the capacitor C and the first resistor R1 in parallel. Similarly, when the secondary-side winding 22 generates the winding voltage Vw, the clamping circuit CC clamps the winding voltage Vw (the current is represented by arrows) to generate the detection voltage Vs at the node P1 between the capacitor C and the first resistor R1, and the capacitor C may also be used to stabilize the voltage level of the detection voltage Vs.

On the other hand, the first voltage detection circuit 70 may also optionally include a diode D and a voltage-dividing circuit CD. The diode D is also used to prevent the current from being reversely flowed back to the secondary side from the first voltage detection circuit 70 when the secondary-side switch SR is switched. The voltage-dividing circuit CD includes a third resistor R3 and a fourth resistor R4 connected between the node P1 and the ground terminal GND in series. The secondary-side controller 5 is coupled to a node P2 between the third resistor R3 and the fourth resistor R4, and the voltage-dividing circuit CD is mainly used to divide the detection voltage Vs into a voltage level suitable for the secondary-side controller 5 to determine.

Please refer to FIG. 5C, which shows a block circuit diagram of the first voltage detection circuit according to a third embodiment of the present disclosure, and also refer to FIG. 1 to FIG. 5B. The difference between the first voltage detection circuit 70 of FIG. 5C and that of FIG. 5A is that the first voltage detection circuit 70 includes an auxiliary winding 24. The auxiliary winding 24 is used to couple the primary-side winding 20, and the polarity of the auxiliary winding 24 and the polarity of the secondary-side winding 22 are the same (i.e., same dotted terminal). When the primary-side current (indicated by arrows) flows from the primary-side winding 20 to the primary-side switch Q, energy is coupled to the secondary-side winding 22 and the auxiliary winding 24 through the primary-side winding 20 so that the auxiliary winding 24 generates the winding voltage Vw. The first voltage detection circuit 70 provides the detection voltage Vs according to the winding voltage Vw of the auxiliary winding 24 so that the secondary-side controller 5 can convert the magnitude of the input voltage Vin according to the magnitude of the detection voltage Vs.

On the other hand, the winding voltage Vw of the auxiliary winding 24 may also be optionally used to supply power to the secondary-side controller 5 so that the secondary-side controller 5 can receive the required detection voltage Vs to control the secondary side. Specifically, the first voltage detection circuit 70 may further include a diode D and a capacitor C. The capacitor C is connected to the auxiliary winding 24 in parallel, and the diode D is coupled between the auxiliary winding 24 and the capacitor C. Specifically, the diode D is used to rectify the winding voltage Vw, and the capacitor C is used to store and stabilize the voltage level of the detection voltage Vs. A power pin of the secondary-side controller 5 is coupled to the capacitor C to receive the detection voltage Vs to be enabled and control the secondary side. In one embodiment, in addition to the implementations of the first voltage detection circuit 70 shown in FIG. 5A to FIG. 5C, the power supply 100 has a variety of circuit structures that can implement the first voltage detection circuit 70. Therefore, any implementation of the first voltage detection circuit 70 that can acquire the input voltage Vin according to the secondary-side winding voltage Vw should be included in the scope of this embodiment. In one embodiment, the detection manner of FIG. 5C is to directly acquire the winding voltage Vw to determine the input voltage Vin. Therefore, in the circuit structure of FIG. 5C, there is no limitation on the secondary-side switch SR being configured at the bus positive terminal 100+ or the bus negative terminal 100− so that the circuit structure of FIG. 5C can increase the applicable range of the power detection circuit 7 and can also simplify the circuit design of the first voltage detection circuit 70.

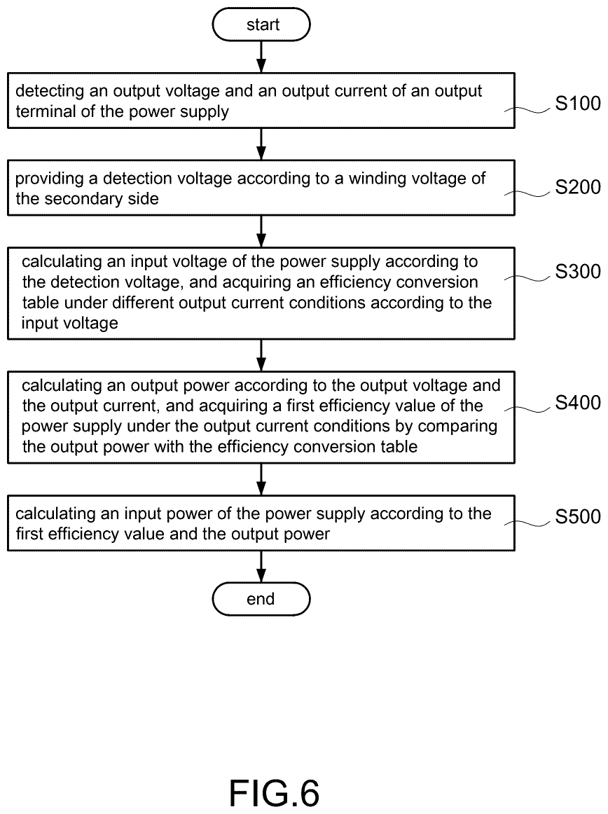

Please refer to FIG. 6, which shows a flowchart of a method of operating the power detection circuit according to the present disclosure, and also refer to FIG. 1 to FIG. 5C. The power supply 100 can realize the function of estimating the input power Pin by only configuring the detection and estimation of the power detection circuit 7 on the secondary side, thereby utilizing fewer components (i.e., the original secondary-side controller 5 with the detection circuit) to achieve the effect of reducing circuit cost and circuit design complexity. Specifically, the method of operating the power detection circuit 7 includes steps of: detecting an output voltage and an output current of an output terminal of the power supply (S100). In a preferred embodiment, the second voltage detection circuit 72 and the current detection circuit 74 are respectively coupled to the output terminal 100A of the power supply 100 to detect the output voltage Vo and the output current Io of the power supply 100. Afterward, providing a detection voltage according to a winding voltage of the secondary side (S200). In a preferred embodiment, the winding voltage Vw in response to the input voltage Vin is detected by the first voltage detection circuit 70, and a detection voltage Vs is provided according to the winding voltage Vw.

Afterward, calculating an input voltage of the power supply according to the detection voltage, and acquiring an efficiency conversion table under different output current conditions according to the input voltage (S300). Since the winding voltage Vw may respond to the input voltage Vin, a preferred embodiment is to use the power detection circuit 7 to calculate the input voltage Vin of the power supply 100 according to the detection voltage Vs so as to acquire the efficiency conversion table Et under different output current conditions according to the input voltage Vin. In particular, the efficiency conversion table Et may be pre-written into the secondary-side controller 5, or the efficiency conversion table Et may be established by testing a testing circuit. Afterward, calculating an output power according to the output voltage and the output current, and acquiring a first efficiency value of the power supply under the output current conditions by comparing the output power with the efficiency conversion table (S400). In a preferred embodiment, the power detection circuit 7 is used to calculate the output power Po according to the output voltage Vo and the output current Io, and the first efficiency value of the power supply 100 under the current output current condition is acquired by comparing the output power Po with the efficiency conversion table Et.

Finally, calculating an input power of the power supply according to the first efficiency value and the output power (S500). In a preferred embodiment, the power detection circuit 7 is used to calculate the input power Pin of the power supply 100 according to the first efficiency value and the output power Po. Therefore, the function of estimating the input power Pin can be realized by using only a few components to detect the parameters of the secondary side. In one embodiment, the detailed operation method of the present disclosure may be also referred to FIG. 1 to FIG. 5C, which will not be described in detail herein. In addition, in one embodiment, the circuits and components in the above-mentioned steps are merely devices more suitable for implementing the above steps, but are not limited thereto. Any circuits and components that can achieve the operation methods in the above steps S100 to S500 should be included in the scope of this embodiment.

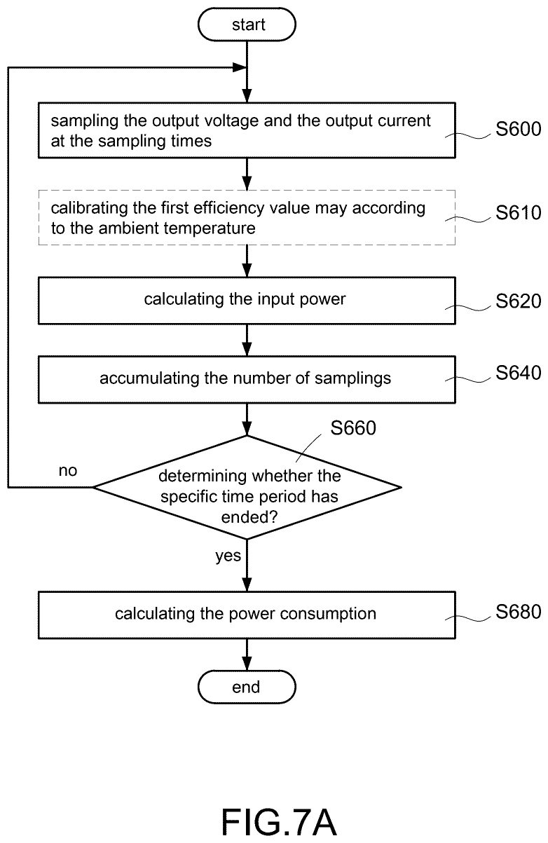

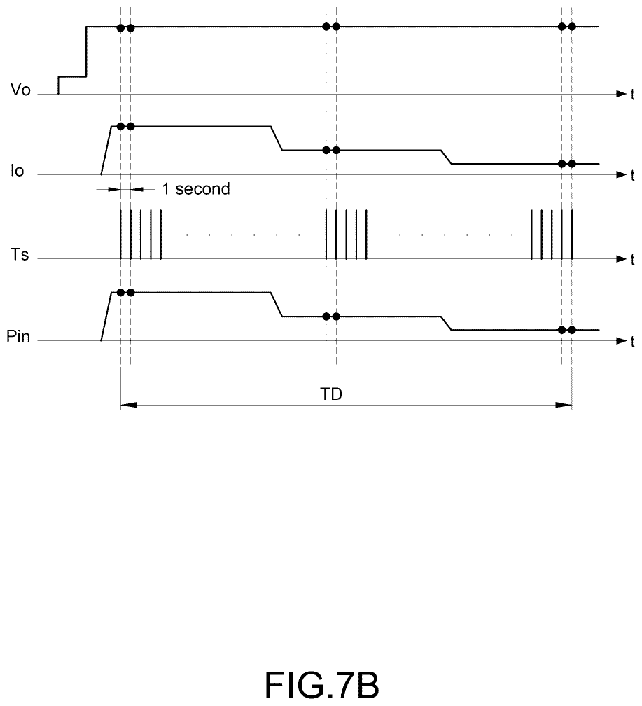

Please refer to FIG. 7A, which shows a flowchart of a method of calculating electric power of a power supply according to the present disclosure; please refer to FIG. 7B, which shows a waveform diagram of the method of calculating electric power of the power supply according to the present disclosure, and also refer to FIG. 1 to FIG. 6. FIG. 7A and FIG. 7B mainly illustrate one application of the power detection circuit 7, which is mainly used for measuring the power consumption of the power supply 100 to calculate the carbon emission of the power supply 100 during operation. Specifically, as shown in FIG. 7A and FIG. 7B, the secondary-side controller 5 may set a specific time period TD (for example but not limited to, 1 hour), and the secondary-side controller 5 may control the first voltage detection circuit 70 to sample the output voltage Vo of the power supply 100 at a plurality of sampling times Ts within the specific time period TD. Furthermore, at the sampling times Ts, the current detection circuit 74 is controlled to sample the output current Io of the power supply 100 (step S600). In one embodiment, FIG. 7B shows a periodic sampling time Ts (for example but not limited to, 1 second), but is not limited thereto, and it may also be a non-periodic sampling time Ts. For example but not limited to, when the output current Io changes, multiple sampling is performed, and when the output current Io does not change, no sampling is performed, and the same logic is applied (for example but not limited to, the change of the ambient temperature), which will not be described in detail herein.

Afterward, the acquired output voltage Vo and output current Io are used to calculate the input power Pin through the operation method of FIG. 6 (step S620). Furthermore, after step S620, the number of samplings starts to be accumulated (step S640), and it is determined whether the specific time period TD has ended (step S660, for example but not limited to, whether 1 hour has passed and 3,600 samples have been taken). When the specific time period TD is not over, the process returns to step S600 to continuously sample the output voltage Vo and the output current Io. On the contrary, when the specific time period TD ends, the power consumption of the power supply 100 in the specific time period TD is acquired according to the accumulated parameters of the input power Pin (step S680, the power consumption may be calculated in kilowatt*hour). Therefore, the carbon emissions of the power supply 100 during operation can be calculated, which is beneficial for the collection and disclosure of carbon emission data.

In addition, between step S600 and step S620, the first efficiency value may be optionally calibrated according to the ambient temperature (step S610). Specifically, the secondary-side controller 5 can control the temperature detection circuit 76 to sample the first ambient temperature of the power supply 100 at the sampling time Ts. The first efficiency value corresponding to each group of output power Po is adjusted according to the first ambient temperature so as to calculate a more accurate input power Pin through the adjusted first efficiency value and the currently acquired output power Po. In one embodiment, FIG. 7A and FIG. 7B are only one of many application methods of the power detection circuit 7 and are not limited to being applied only to calculating electric power.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A power detection circuit configured in a power supply comprising a primary side and a secondary side, the power detection circuit comprising:
a secondary-side controller configured in the secondary side,
a first voltage detection circuit coupled to the secondary-side controller, and configured to provide a detection voltage according to a winding voltage of the secondary side,
a second voltage detection circuit coupled to the secondary-side controller and an output terminal of the power supply, and configured to detect an output voltage of the output terminal, and
a current detection circuit coupled to the secondary-side controller and the output terminal, and configured to detect an output current of the output terminal,
wherein the secondary-side controller is configured to calculate an input voltage of the power supply according to the detection voltage, and acquire an efficiency conversion table under different output current conditions according to the input voltage; the secondary-side controller is configured to calculate an output power according to the output voltage and the output current, acquire a first efficiency value of the power supply under the output current conditions by comparing the output power with the efficiency conversion table, and calculate an input power of the power supply according to the first efficiency value and the output power.

2. The power detection circuit as claimed in claim 1, further comprising:
a temperature detection circuit coupled to the secondary-side controller, and configured to detect a first ambient temperature of the power supply,
wherein the secondary-side controller is configured to adjust the first efficiency value according to the first ambient temperature.

3. The power detection circuit as claimed in claim 2, wherein the secondary-side controller is configured to preset a plurality of second ambient temperatures, and a plurality of second conversion efficiency values under different output current conditions are acquired according to the plurality of second ambient temperatures; the secondary-side controller is configured to calculate a parameter difference between the first ambient temperature and two adjacent second ambient temperatures by an interpolation calculation to acquire the first efficiency value corresponding to the first ambient temperature.

4. The power detection circuit as claimed in claim 2, wherein the temperature detection circuit comprises:
a temperature-controlled resistor configured to generate a temperature control value according to the first ambient temperature, and the secondary-side controller configured to realize the first ambient temperature according to the temperature control value, and adjust the first efficiency value according to the first ambient temperature.

5. The power detection circuit as claimed in claim 1, wherein the secondary side comprises a secondary-side switch configured in a bus positive terminal, and the first voltage detection circuit comprises:
a voltage-dividing circuit coupled between a bus negative terminal of the secondary side and a ground terminal, and comprising a first resistor and a second resistor connected in series,
wherein when the secondary-side switch is not turned on, the voltage-dividing circuit is configured to divide the winding voltage of a secondary-side winding of the secondary side to generate the detection voltage at a node between the first resistor and the second resistor.

6. The power detection circuit as claimed in claim 1, wherein the secondary side comprises a secondary-side switch configured in a bus negative terminal, and the first voltage detection circuit comprises:
a clamping circuit coupled between a bus positive terminal of the secondary side and a ground terminal, and comprising a capacitor and a first resistor connected in series, and a second resistor connected to the capacitor and the first resistor in parallel,
wherein when the secondary-side switch is not turned on, the clamping circuit is configured to clamp the winding voltage of a secondary-side winding of the secondary side to generate the detection voltage at a node between the capacitor and the first resistor.

7. The power detection circuit as claimed in claim 1, wherein the first voltage detection circuit comprises:
an auxiliary winding coupled to a primary-side winding of the primary side, and the first voltage detection circuit configured to provide the detection voltage according to the winding voltage of the auxiliary winding.

8. The power detection circuit as claimed in claim 1, wherein the first voltage detection circuit is configured to sample a plurality of output voltages at a plurality of sampling times within a specific time period, and the current detection circuit is configured to sample a plurality of output currents at the sampling times; the secondary-side controller is configured to calculate a plurality of input powers corresponding to the output voltages and the output currents, and acquire an electric power of the power supply in the specific time period according to the input powers.

9. The power detection circuit as claimed in claim 8, wherein the secondary-side controller is configured to detect a plurality of first ambient temperatures of the power supply at the sampling times respectively, and adjust a plurality of first efficiency values corresponding to the first ambient temperatures.

10. A method of operating a power detection circuit, the power detection circuit configured in a power supply comprising a primary side and a secondary side, the method comprising steps of:
detecting an output voltage and an output current of an output terminal of the power supply,
providing a detection voltage according to a winding voltage of the secondary side,
calculating an input voltage of the power supply according to the detection voltage, and acquiring an efficiency conversion table under different output current conditions according to the input voltage,
calculating an output power according to the output voltage and the output current, and acquiring a first efficiency value of the power supply under the output current conditions by comparing the output power with the efficiency conversion table, and
calculating an input power of the power supply according to the first efficiency value and the output power.
